(19) United States
(12) Patent Application Publication
(10) Pub. No.: US 2006/0027906 A1
(43) Pub. Date: Feb. 9, 2006

(54) Exclusive memory structure applicable for multi media card and secure digital card

(76) Inventors: Sheng-Chih Hsu, Taipei (TW); Yun-Chiang Wang, Taipei (TW)

Correspondence Address: SUPREME PATENT SERVICES, P.O. BOX 2339, SARATOGA, CA, 95070-0339, US

(21) Appl. No.: 10/911,343

(22) Filed: Aug. 3, 2004

(51) Int. Cl. H01L 23/02

(52) U.S. Cl. 257/685; 257/681

(57) ABSTRACT

An exclusive memory structure applicable for Multi Media Card and Secure Digital Card includes a casing and a substrate, in which the substrate is attached to the casing; a control chip and two or more flash-memory chips are disposed on the substrate; and a plurality of connecting pieces is arranged on the bottom face of the substrate, whereby the storage capacity of a memory card could be enlarged and data could be stored by way of splitting.

### BACKGROUND OF THE INVENTION

1. Field of the Invention

An exclusive memory structure of the present invention is applicable to electronic memory cards, particularly to a Multi Media Card (MMC) and a Secure Digital (SD) Card for splitting data to be stored in addition to enlarging the storage capacity thereof.

2. The Prior Arts

The Multi Media Card and Secure Digital Card are operated through a single flash-memory chip, in which the data storage capacity thereof is dependent on the chip makers, and the data access manner is somewhat disordered, and besides, it is irremediable as long as a card like this is damaged.

### SUMMARY OF THE INVENTION

The primary object of the present invention is to enlarge the storage capacity and store data in a splitting manner of a Multi Media Card and a Secure Digital Card.

In order to realize the object, an exclusive memory structure applicable for Multi Media Card and Secure Digital Card is mainly comprised of a casing and a substrate, in which the substrate is attached to the casing; a control chip and more than two flash-memory chips are disposed on the substrate; and, a plurality of connecting pieces is arranged on the bottom face of the substrate, whereby the storage capacity of a memory card could be enlarged and data could be stored by way of splitting.

The merits of the present invention may be summarized as follows: (1) Enlargement of storage capacity of Multi Media Card and Secure Digital Card by using the present invention is possible. (2) To split then store data systematically is possible. (3) The memory card is still workable in case a single flash-memory chip is damaged, so that data loss could be significantly avoided.

For more detailed information regarding advantages or features of the present invention, at least an example of preferred embodiment will be described below with reference to the annexed drawings.

### BRIEF DESCRIPTION OF THE DRAWINGS

The related drawings in connection with the detailed description of the present invention to be made later are described briefly as follows, in which:

FIG. 1 is a perspective view of an exclusive memory structure of the present invention;

FIG. 2 is an exploded view of the present invention; and

FIG. 3 shows an embodiment of the present invention.

### DETAILED DESCRIPTION OF THE PREFERRED EMBODIMENT

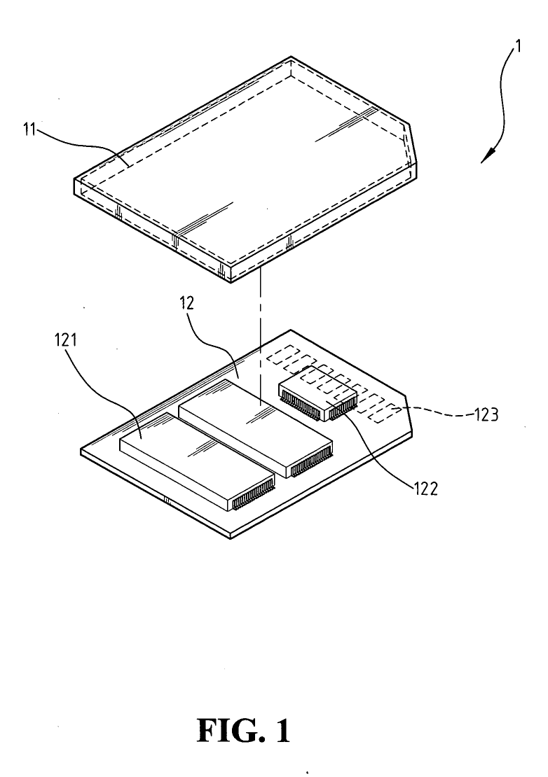

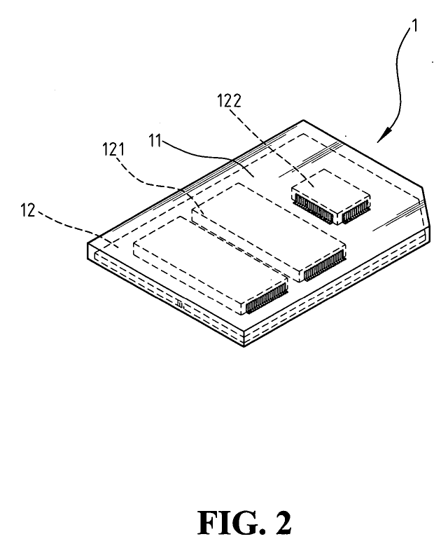

An exclusive memory structure applicable for Multi Media Card and Secure Digital Card 1 shown in FIGS. 1 and 2 of the present invention comprises a casing 11 and a substrate 12 attached to the casing 11, in which a control chip 122 and two or more flash-memory chips 121 are disposed on the substrate 12. Preferably, there are 2 or 3 flash-memory chips 121. A plurality of connecting pieces 123 is arranged on the bottom face of the substrate 12, which is employed to connect with a R/W device for data transmission and split data for storage systematically.

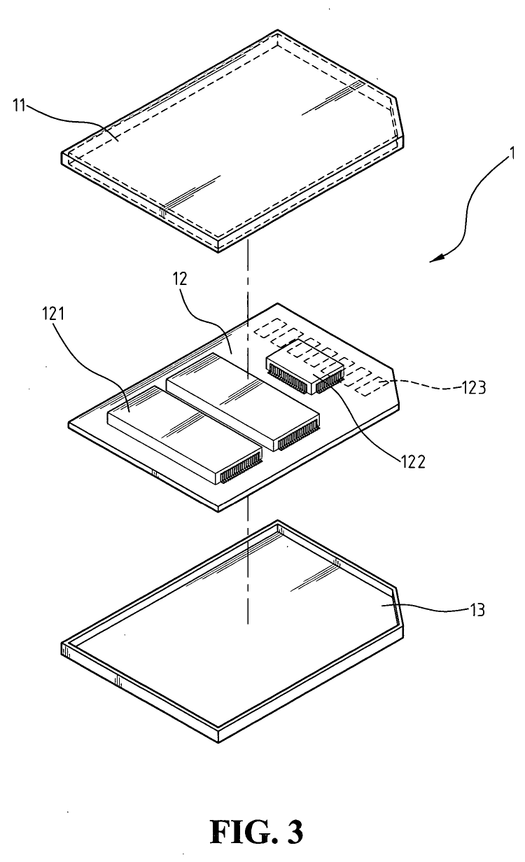

Also referring to FIG. 3, an exclusive memory structure applicable for Multi Media Card and Secure Digital Card of the present invention comprises a casing and a substrate attached to the casing, in which a lower casing 13 is additionally arranged under the casing 11 such that the substrate 12 is invested, if so requested according to the specification of the memory cards.

In the above described, at least one preferred embodiment has been described in detail with reference to the drawings annexed, and it is apparent that numerous changes or modifications may be made without departing from the true spirit and scope thereof, as set forth in the claims below.

What is claimed is:

1. An exclusive memory structure applicable for Multi Media Card and Secure Digital Card, comprising: a casing having a substrate attached together, in which a control chip and at least two flash-memory chips are arranged on the substrate; and a plurality of connecting pieces is disposed on a bottom face of the substrate.

2. The exclusive memory structure according to claim 1, wherein three flash-memory chips are arranged on the substrate.

3. The exclusive memory structure according to claim 1, wherein which a lower casing is arranged under the casing.
